(19) United States
(12) Patent Application Publication
(10) Pub. No.: US 2011/0049659 A1
(43) Pub. Date: Mar. 3, 2011

(54) MAGNETIZATION CONTROL METHOD, INFORMATION STORAGE METHOD, INFORMATION STORAGE ELEMENT, AND MAGNETIC FUNCTION ELEMENT

(76) Inventors: Yoshishige Suzuki, Osaka (JP); Takayuki Nozaki, Osaka (JP); Takuto Maruyama, Osaka (JP); Yoichi Shiota, Osaka (JP)

(21) Appl. No.: 12/990,524

(22) PCT Filed: Feb. 27, 2009
(86) PCT No.: PCT/JP2009/000899

§ 371 Date: Nov. 17, 2010

(30) Foreign Application Priority Data
May 2, 2008 (JP) 2008-120614

(51) Int. Cl. H01L 43/06; H01F 13/00

(52) U.S. Cl. 257/421; 335/284; 257/E43.002

(57) ABSTRACT

The present invention provides a magnetization control method controlling, utilizing no current-induced magnetic field or spin transfer torque a magnetization direction with low power consumption, an information storage method, an information storage element, and a magnetic function element. The magnetization control method involves controlling a magnetization direction of a magnetic layer, and includes: forming a structure including (i) the magnetic layer which is an ultrathin film ferromagnetic layer having a film thickness of one or more atomic layers and of 2 nm or less, and (ii) an insulating layer provided on the ultrathin film ferromagnetic layer and working as a potential barrier; and controlling a magnetization direction of the ultrathin film ferromagnetic layer by applying either (i) a voltage to opposing electrodes sandwiching the structure and a base layer or (ii) an electric field to the structure to change magnetic anisotropy of the ultrathin film ferromagnetic layer. The magnetization control method further involves controlling a waveform of the applied voltage or the applied electric field to switch the magnetization direction.

### TECHNICAL FIELD

The present invention relates to a magnetization control method employing an electric field, an information storage method utilizing the magnetization control method, and a magnetic function element. In particular, the present invention relates to a nonvolatile magnetic random access memory and a spin transistor which contributes to a nonvolatile logic.

### BACKGROUND ART

Since the 1990's, there has been a rapid popularization of IT devices such as personal computers and cellular phones at a common household level, and further, at an individual level. Nowadays, the IT devices are an absolute necessity in day-to-day living. The prevailing IT devices have depended on such major Large Scale Integrations (LSI) as a Dynamic Random Access Memory (DRAM) and a flash memory. The growth of the IT device market is going to continue; accordingly, products leading the memory LSI market are expected to definitely spread from the conventional market centered on PCs and cellular phones to the third market dominated by mobile terminals and information home appliances. The memories and logic circuits used for such devices require a low-power driving capability, as well as a large capacity and a high-speed response capability. For the memories, in particular, nonvolatility is essential for low power consumption. Thus, universal memories satisfying all the above characteristics is actively being developed. The flash memory is a nonvolatile memory that is popular nowadays. However, since the flash memory works on the principle of charge injection, many problems have to be overcome in order for the flash memory to be a universal memory. These problems include a low writing speed that is in the μs order, and a low rewriting frequency that is in the 10⁶ range.

Concurrently, the Magneto-Resistive-Effect Magnetic Random Access Memory (MRAM) is recently attracting attention (See Non Patent Reference 1) as a nonvolatile memory. In the MRAM, stacked structures including magnetic elements are arranged in a matrix, and the Magneto-Resistance Effect of the magnetic elements is used to read each piece of element storage information. When writing information, the MRAM controls magnetization directions of the magnetic elements to write the information. The MRAM employs a magnetized state as a storage state, and is thus nonvolatile in principle. As a result, the MRAM holds great promise as a nonvolatile memory that can satisfy all requirements such as: a low power consumption capability, a high-speed capability, a large capacity, sufficient write endurance, and close conformity to a semiconductor. However, with regard to writing methods, there is a high possibility for increased power consumption when facing a large amount of data exceeding giga-bit levels, and this is perceived to be a problem.

In general, two techniques have been proposed as magnetization direction control techniques applicable to the MRAM. One of the techniques is a typical one employing a current-induced magnetic field. This technique uses a wire disposed very close to a target magnetic element. However, this technique might not be able to handle a large amount of capacity, such as over giga-bit levels, because of the following problems: (i) a greater amount of current is required as the size of the magnetic element decreases; (ii) and a writing error develops in a magnetic element close to the target magnetic element due to a fringing field from a wire. The other technique, a promising one which possibly solves those problems, employs the spin transfer torque (See Non Patent Reference 2). The spin transfer torque is a phenomenon caused by directly transferring spin angular momentum of a conduction electron to a localized spin of a magnetic element to be reversed. In the spin transfer torque, the current density required for the reversal does not depend on an element size. Hence, in principle, a required writing current becomes smaller as the size of an element decreases. The spin transfer torque technique has caught attention as an encouraging writing technique for the next-generation MRAM; however, the critical current density required for writing is not sufficiently low enough at the moment. Thus, unfortunately, the technique has not achieved a low power consumption capability which surpasses that of competing memories.

Still, other techniques have been proposed to induce a magnetic response using a field effect to an element. For example, Non Patent Reference 3 introduces a technique to use a sandwich laminate having a very thin semiconductor layer sandwiched between two ferromagnetic layers. In the sandwich laminate, controlling carrier concentration in the semiconductor layer by an applied electric field changes magnetic interlayer exchange coupling generated via the semiconductor layer. Furthermore, a technique proposed in Patent Reference 1 involves (i) growing a ferromagnetic layer/nonmagnetic layer/ferromagnetic layer sandwich laminate on a semiconductor (or an insulator) and, taking advantage of a change of a surface barrier height, developed by application of a voltage, on an interface of the semiconductor (or the insulator) and of the ferromagnetic layers, (ii) controlling interlayer exchange coupling found between ferromagnetic layers having nonmagnetic layer in between. The above technique, utilizing magnetization reversal control employing electric field stimulation, possibly achieves information writing with low power consumption, rather than the techniques utilizing a current-induced magnetic field (external magnetic field) or the spin transfer effect. Hence, the technique disclosed in Patent Reference 1 holds promise for application to a nonvolatile and small magnetic random access memory.

There is also a patent related to the present invention: the magnetization reversal control technique disclosed in Patent Reference 2. The magnetization reversal control technique achieves local magnetization reversal via (i) application of a high electric field from a needle-like metal chip to a magnetic thin film to locally control magnetic anisotropy of the magnetic thin film, followed by (ii) external application of a magnetic filed to the magnetic thin film. In other words, the magnetization reversal control technique involves controlling a position of an externally-driven metal chip with respect to a magnetic medium so as to write magnetically recorded information to any given location. This technique is intended to be applied to a mass storage medium, such as a hard disk, and thus application to a magnetic random access memory is difficult. Non Patent Reference 4 discloses that controlling magnetic anisotropy of a magnetic thin film is possible through the application of a high electric field to a ferromagnetic FePt thin film and a ferromagnetic FePd thin film via electrolytes. This phenomenon is produced when the high electric field is achieved employing an electric double layer formed on an electrolyte/ferromagnetic layer interface. The use of the electrolytes, however, makes a configuration of a magnetic random access memory difficult. Furthermore, Patent Reference 3 proposes a technique to control a magnetized state utilizing induction of magnetostriction by placing a magnetic body in contact with a piezoelectric and electrostrictive material, such as PZT which can induce an electrical stimulus. Under the existing conditions, unfortunately, the piezoelectric and electrostrictive material is short of fatigue resistance.

Patent Reference 1: Japanese Unexamined Patent Application Publication No. 2001-196661

Patent Reference 2: European Patent No. 1099217

Patent Reference 3: Japanese Unexamined Patent Application Publication No. 2001-028446

Non Patent Reference 1: C. Chappert et al. Nature materials, 6, 813 (2007).

Non Patent Reference 2: J. C. Slonczewski, J. Magn. Magn. Mater. 159, L1 (1996).

Non Patent Reference 3: J. E. Mattsonet et al. Phys. Rev. Lett. 71, 185 (1993)

Non Patent Reference 4: M. Weisheit et al. Science 315, 349 (2007).

Non Patent Reference 5: H. Ohono et al. Nature 408, 944 (2007).

### DISCLOSURE OF INVENTION

### Problems that Invention is to Solve

Regarding the techniques described in Non Patent Reference 3 and Patent Reference 1, specifically the techniques to induce a magnetic response using the field effect, no successful result has been reported in an application stage, not to mention in a basic research stage. In addition, in the case where the magnetization reversal control utilizing an electric field involves controlling a surface barrier height of a semiconductor or an insulator so as to change interlayer exchange coupling strength of the ferromagnetic layer/nonmagnetic layer/ferromagnetic layer sandwich laminate, the quantum interference effect to cause the interlayer exchange coupling needs to grow among plural layers. This requires a significantly high-quality stacked structure. For example, epitaxially-grown Fe/Au- and Fe/Cr-based materials are the only successful cases in which vibration of interlayer exchange coupling, in structure including the ferromagnetic layer, is observed. Furthermore, the techniques described in Patent References 1 to 3 and Non Patent References 1 to 5 cannot produce a magnetic random access memory at room temperature because of the above reasons.

The present invention is conceived in view of the above problems and has as an object to provide (i) a magnetization control method of controlling a magnetization direction with low power consumption and without using a current-induced magnetic field or spin transfer torque, (ii) an information storage method, (iii) an information storage element, and (iii) a magnetic function element.

### Means to Solve the Problems

In order to solve the above problems, a magnetization control method according to an implementation of the present invention involves controlling a magnetization direction of a magnetic layer. The magnetization control method includes: forming a structure including (i) an ultrathin film ferromagnetic layer having a film thickness of one or more atomic layers and of 2 nm or less, and (ii) an insulating layer provided on the ultrathin film ferromagnetic layer and working as a potential barrier; and controlling a magnetization direction of the ultrathin film ferromagnetic layer by applying either (i) a voltage to opposing electrodes sandwiching the structure or (ii) an electric field to the structure to change magnetic anisotropy of the ultrathin film ferromagnetic layer.

The use of above the magnetization control method can control the magnetization direction with low power consumption utilizing no current-induced magnetic field or spin transfer torque. Such controlling of the magnetization direction makes possible producing a spin transistor which contributes to a nonvolatile magnetic random access memory and a nonvolatile logic with very low power consumption.

Preferably, the forming the structure includes forming, as the insulating layer, an insulating layer having a value of resistance per unit area of 10 Ωm² or greater.

Preferably, the forming the structure includes determining a film thickness of the ultrathin film ferromagnetic layer so that the film thickness develops, in the ultrathin film ferromagnetic layer, transition between in-plane magnetic anisotropy and shape magnetic anisotropy, the transition being caused by an electric field generated on an interface between the ultrathin film ferromagnetic layer and the insulating layer.

Preferably, the controlling involves applying the voltage so that perpendicular magnetic anisotropy energy generated in the ultrathin film ferromagnetic layer accounts for 50% to 99% of shape magnetic anisotropy energy observed when the magnetization is oriented perpendicular to a plane.

Preferably, the controlling involves applying, as the voltage, a voltage changing stepwise.

Preferably, the controlling involves applying, as the voltage, a pulse voltage (i) whose rising time period is equal to or shorter than a magnetic relaxation time period of the ultrathin film ferromagnetic layer, and (ii) whose falling time period is equal to the magnetic relaxation time period of the ultrathin film ferromagnetic layer or longer.

Preferably, the controlling involves sweeping voltages having opposite polarities and applying the voltages to the structure in order to control the magnetization direction of the ultrathin film ferromagnetic layer.

A method according to another aspect of the present invention is a method for storing information which involves executing the magnetization control method to control a magnetization direction.

An element according to another aspect of the present invention is an information storage element including: an ultrathin film ferromagnetic layer having a film thickness of one or more atomic layers and of 2 nm or less; an insulating layer provided on the ultrathin film ferromagnetic layer and working as a potential barrier; and a pair of opposing electrodes sandwiching the ultrathin film ferromagnetic layer and the insulating layer.

Preferably, the information storage element further includes a reference layer sandwiched between the opposing electrodes, provided opposite the insulating layer in relation to the ultrathin film ferromagnetic layer, and including a ferromagnetic metal.

Preferably, the information storage element further includes a substrate, wherein one of the opposing electrodes is a base layer provided on the substrate, and working as a base to grow the ultrathin film ferromagnetic layer or the reference layer

A magnetic function element according to another aspect of the present invention works as at least one of a memory and a switch. The magnetic function element includes: a first electrode layer connected to a first terminal; a first magnetic layer which is an ultrathin film ferromagnetic layer (i) provided on first electrode layer, and (ii) having a film thickness of one or more atomic layers and of 2 nm or less; an insulating layer provided on a part of a top surface of the first magnetic layer, and working as a potential barrier; a second electrode layer formed on the insulating layer and connected to a second terminal; a nonmagnetic layer provided on an other part of the top surface of the first magnetic layer; a second magnetic layer provided on the nonmagnetic layer; and a third electrode layer provided on the second magnetic layer, and connected to the third terminal.

A magnetic function element according to another aspect of the present invention works as at least one of a memory and a switch. The magnetic function element includes: a first magnetic layer which is an ultrathin film ferromagnetic layer having a film thickness of one or more atomic layers and of 2 nm or less; an insulating layer working as a potential barrier, and provided in contact with a bottom surface of the first magnetic layer; a first electrode layer formed under the insulating layer and connected to the first terminal; a nonmagnetic layer provided on the first magnetic layer; and a second magnetic layer provided on the nonmagnetic layer; a second electrode layer provided on a part of a top surface of the second magnetic layer, and connected to the second terminal; and a third electrode layer provided on an other part of the top surface of the second magnetic layer, and connected to the third terminal.

A magnetic function element according to another aspect of the present invention works as at least one of a memory and a switch. The magnetic function element includes: a first magnetic layer; a nonmagnetic layer provided on said first magnetic layer; a second magnetic layer which is an ultrathin film ferromagnetic layer (i) provided on said nonmagnetic layer, and (ii) having a film thickness of one or more atomic layers and of 2 nm or less; an insulating layer provided on a part of a top surface of said second magnetic layer, and working as a potential barrier; a first electrode layer formed on said insulating layer and connected to a first terminal; and a second electrode layer and a third electrode layer both provided on other parts of the top surface of said second magnetic layer, and respectively connected to a second terminal and a third terminal.

The above structures make possible (i) achieving an information storage method and (ii) producing an information storage element and a magnetic function element that are capable of controlling a magnetization direction with lower power consumption than conventional techniques. As a result, a conventional magnetic storage technique used for an MRAM can be utilized, eliminating the need for an electrode for current-induced magnetic field application and high writing current density required to induce the spin transfer effect.

### EFFECTS OF THE INVENTION

The present invention can control a magnetization direction without using a current-induced magnetic field and spin transfer torque. Furthermore, each independent element is capable of working as a random access magnetic memory including an insulating layer for applying an electric field and a magnetic layer controlling anisotropy. Moreover, since the resistance value (gate resistance) between (i) a voltage application terminal for controlling a magnetization direction and (ii) an ultrathin film ferromagnetic layer can be increased significantly, the present invention can provide a multiterminal magnetic function element (spin transistor) having no interference with an output circuit. The provision of such a multiterminal magnetic function element (i) solves problems in the conventional techniques such as an increase in writing current and items of concern such as fringing fields, and (ii) produces a non-volatile and frequently-rewritable magnetic random access memory with low power consumption, and a magnetic function element such as a spin transistor which contributes to a nonvolatile logic.

### BRIEF DESCRIPTION OF DRAWINGS

FIG. 1 is a cross-sectional view of a magnetic function element according to Embodiment 1 in the present invention.

FIG. 2 shows an experiment result on the magnetic function element according to Embodiment 1.

FIG. 3 shows the fact that magnetization reversal can be controlled employing a change in perpendicular magnetic anisotropy caused by a voltage and an electric field generated out of the voltage.

FIG. 4 shows an experiment result on the magnetic function element according to Embodiment 1.

FIG. 5 shows an experiment result on the magnetic function element according to Embodiment 1.

FIG. 6 shows an experiment result on the magnetic function element according to Embodiment 1.

FIG. 7 shows an experiment result on the magnetic function element according to Embodiment 1.

FIG. 8 shows an experiment result on the magnetic function element according to Embodiment 1.

FIG. 9 shows dependency on an insulating material of performance characteristics of the magnetic function element according to Embodiment 1.

FIG. 10 is a cross-sectional view of a magnetic function element according to Embodiment 2 in the present invention.

FIG. 11 is a cross-sectional view of a magnetic storage element according to Embodiment 3 in the present invention.

FIG. 12 is a cross-sectional view of a magnetic storage element according to Embodiment 4 in the present invention.

FIG. 13 shows a structure of a spin transistor according to Embodiment 5 in the present invention.

FIG. 14 is a cross-sectional view of a magnetic function element according to Embodiment 6 in the present invention.

FIG. 15 is a cross-sectional view of a magnetic function element according to Embodiment 7 in the present invention.

FIG. 16 is a cross-sectional view of a magnetic function element according to Embodiment 8 in the present invention.

### NUMERICAL REFERENCES

10, 31, and 42 Magnetic layer

11 Insulating layer

12, 30, 32, 43, 44, and 50 Electrode

13 Substrate

14 Base layer

20 Reference layer

21 Storage layer

33 and 41 Nonmagnetic layer

100 Semiconductor layer

101 First magnetic layer

102 First electrode

103 Second magnetic layer

104 Second electrode

105 Gate insulating film

106 Third electrode

### BEST MODE FOR CARRYING OUT THE INVENTION

Embodiments in the present invention with reference to the drawings are detailed hereinafter.

### Embodiment 1

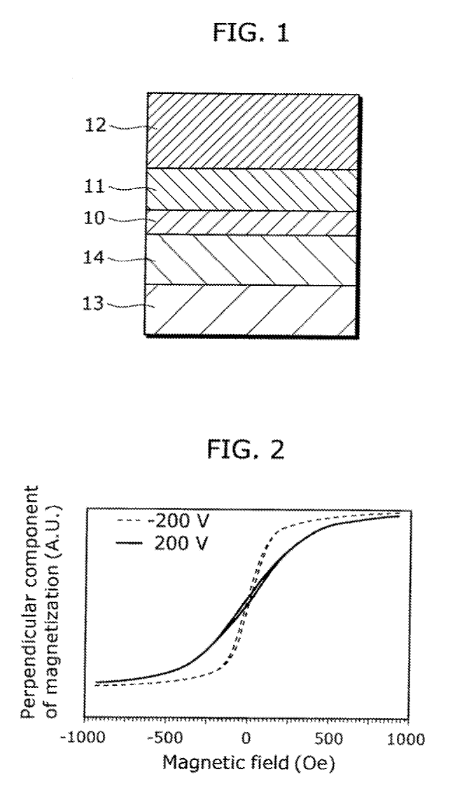

FIG. 1 is a cross-sectional view of a magnetic function element according to Embodiment 1 in the present invention.

In the magnetic function element, a magnetic layer 10, which is to be magnetically-controlled by having a voltage applied, is provided on a substrate 13 via a base layer 14; and an insulating layer 11, which works as a potential barrier, is provided in contact with the magnetic layer 10. Above the insulating layer 11, an electrode 12 is provided to apply a voltage to the magnetic layer 10.

The following substrates, for example, can be used as the substrate 13: a semiconductor substrate such as a silicon substrate, a plastic substrate, a glass substrate, a sapphire substrate, and a magnesium oxide substrate; and an insulating substrate.

The base layer 14 may be formed of: a layer made of (i) a noble metal including the following: gold (Au), silver (Ag), copper (Cu), aluminum (Al), chrome (Cr), and ruthenium (Ru), and (ii) a transition metal element; and a stacked structure including such a layer. The base layer 14 is also used as a bottom electrode layer.

The magnetic layer 10 has a thickness that allows transition between in-plane magnetic anisotropy and shape magnetic anisotropy to occur in the magnetic layer due to the electric field in the interface between the magnetic layer and the insulating layer 11. The magnetic layer 10 may employ a layer including, for example, (i) a magnetic element, such as iron (Fe), cobalt (Co), and nickel (Ni), (ii) an alloy made of a magnetic element; (iii) a magnetic alloy; (iv) an oxidative product (ferrite); and (v) a chemical compound and an alloy including (a) a magnetic element and (b) rare-earth element neodymium (Nd), and samarium (Sm), and terbium (Tb). The magnetic layer 10 may also employ a layer including one of an alloy, an ordered alloy, and a multilayer laminated structure each made of (i) one of Fe, Co, and Ni as a magnetic transition metal, and (ii) one of Pt, Pd, Ru, and Re. When the magnetic layer 10 is made of an iron-cobalt alloy, it is preferable that the Co composition be suppressed to less than 30% so that the change of interfacial magnetic anisotropy energy in the interface between the magnetic layer 10 and the insulating layer 11 is equal to 5 μJ/m² or greater. Here, the energy change is caused by the application of a voltage to the electrode 12 and the base layer 14 or the application of an electric field to the magnetic layer 10 and the insulating layer 11.

The insulating layer 11 has a value of resistance per unit area of 10 Ωm² or greater. The insulating layer 11 may be formed of a layer made of an oxide, a nitride, and a fluoride of the following: aluminum, magnesium, hafnium, cerium, strontium, tantalum, and titan. However, since the energy change of the magnetic anisotropy of the magnetic layer 10, caused by (i) voltage application to the electrode 12 and the base layer 14 or (ii) electric field application to the magnetic layer 10 and the insulating layer 11, depends on an amount of charge accumulated in the interface between the magnetic layer 10 and the insulating layer 11, it is preferable that the material of the insulating layer 11 be a paraelectric having relative permittivity higher than magnesium oxide (relative permittivity of 9.8) at room temperature.

In a magnetic function element structured as described above, a voltage is applied to the electrode 12 and the base layer 14 so that the perpendicular magnetic anisotropy generated in the magnetic layer 10 accounts for 50% to 99% of shape magnetic anisotropy energy observed when a magnetization direction is oriented perpendicular to the plane. Alternatively, a pulse voltage may be applied to the electrode 12 and the base layer 14. Here, the pulse voltage has the following features: the rising time period of the pulse voltage is equal to or shorter than a magnetic relaxation time period of the magnetic layer 10, and the falling time period is equal to the magnetic relaxation time period of the magnetic layer 10 or longer; and the pulse voltage changes stepwise. Alternatively, voltages having opposite polarities may be swept to be applied to the electrode 12 and the base layer 14 so that the magnetization direction of the magnetic layer 10 is controlled.

FIG. 2 is a verification example obtained from an experiment. FIG. 2 shows the result of an experiment conducted as follows: a voltage is externally applied to a magnetic function element having a stacked structure, such as the substrate 13/the base layer 14/the magnetic layer 10/the insulating layer 11/the electrode 12; and the change of the magnetic anisotropy of the magnetic function element is detected as a change of a magnetic hysteresis loop, employing the Magneto-Optical effect (Polar MOKE, or Polar Magneto-Optical Kerr Effect). The substrate 13 is made of magnesium oxide single crystals (001). The base layer 14 is formed of epitaxial multilayer films (001) made of gold and chrome. The magnetic layer 10 is formed of an Fe (001) film (4.5 Å in film thickness). The insulating layer 11 is formed of an MgO (001) layer (10 nm)/polyimide (1.5 μm) stacked film. The upper electrode 12 is made of indium tin oxide (ITO).

An ultrathin film Fe on an epitaxial Au (001) is well known to show the perpendicular magnetic anisotropy within a range of several angstroms in film thickness. As shown in FIG. 2, when a direct current (DC) voltage of 200V is applied to the magnetic function element, approximately 40% of the perpendicular magnetic anisotropy has changed compared with perpendicular magnetic anisotropy in an equilibrium state. The magnetic function element requires a high voltage due to the polyimide (1.5 μm) stacked film; however, forming the upper electrode 12 directly on the MgO (001) layer (thicker than 1 nm) makes possible achieving the same effect with a voltage equal to 1V or lower. An essential point here is that, due to a problem of symmetry, the change of anisotropy, which is supposedly caused by an electric field orienting perpendicular to a film surface, is not induced with respect to an in-plane magnetization film, and even in the case where the perpendicular magnetic anisotropy is extremely strong, the electric field has little effect, and thus, control is difficult. In the magnetic function element in Embodiment 1, the film thickness of the ultrathin film Fe, that is the magnetic layer 10, is properly designed. Thus, the magnetic function element can select a region in which the in-plane magnetic anisotropy transits to the perpendicular magnetic anisotropy, and maximally convert the effect of the electric field to magnetic anisotropy change. This phenomenon occurs when the electric field is applied to the interface between the magnetic layer 10 and the insulating layer 11. Here, the magnetic anisotropy energy is expressed as follows:

$${E}_{ani} = ( \frac{1}{2} {μ}_{0} {M}^{2} - {K}_{u} - \frac{{K}_{s}}{d} - \frac{{K}_{E}}{d} V ) {cos}^{2} θ - {μ}_{0} {MH}_{ext} cos θ \qquad [ Equation 1 ]$$

where θ is an angle formed by magnetization and a normal line of a film, M is the magnetization, μ₀ is magnetic permeability in vacuum, Kᵤ is uniaxial anisotropy energy, Kₛ is surface anisotropy energy, K_{E} is a change rate of magnetic anisotropy caused by voltage application, Hₑₓₜ is a degree of an external magnetic field applied perpendicular to a film surface, d is a film thickness of the magnetic layer 10, and V is an applied voltage. Here, a change rate of a component M_{y} is calculated below. The component M_{y} is the magnetization perpendicular to the film, and with respect to a voltage.

$$\frac{d {M}_{y}}{d V} = \frac{M}{\frac{1}{2} {μ}_{0} {M}^{2} - {K}_{u} - \frac{{K}_{s}}{d}} \frac{{K}_{E}}{d} \qquad [ Equation 2 ]$$

As Expression 2 clearly shows, perpendicular magnetic anisotropy energy (Kᵤ−Kₛ/d) generated in the magnetic layer 10 is set to 50 to 99% of shape magnetic anisotropy (μ₀−M²/2) observed when a magnetization develops perpendicular to the surface. As a result, the change rate of the component with respect to the voltage can be greater. Such a change rate is greater as the perpendicular magnetic anisotropy energy is greater; simultaneously though, heat fluctuations in the magnetization end in an increase. Thus a greater change rate is not desirable from a practical viewpoint. Moreover, a smaller film thickness d of the magnetic layer 10 contributes to a greater change rate of the component with respect to the voltage. However, when the film thickness becomes smaller than a single atomic layer, a ferromagnetic state cannot be sustained, which produces an undesirable result. In addition, when the film thickness is too small, a problem occurs in that the tunneling magnetoresistive effect is reduced. Thus, the film thickness d of the magnetic layer 10 is desirably as thick as a single atomic layer or greater and as thin as 2 nm or smaller.

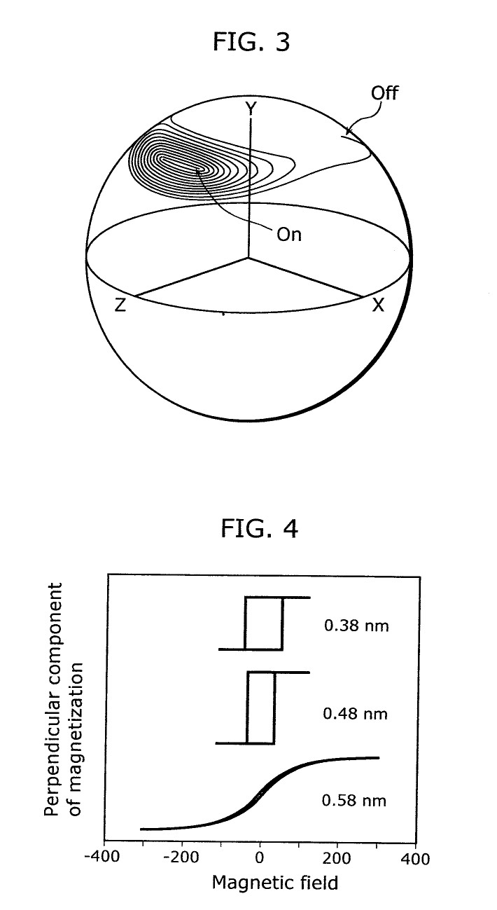

Next, the after-described simulation based on the macro spin model shows how the magnetization reversal control is possible utilizing the perpendicular magnetic anisotropy change caused by a voltage and an electric field generated by the voltage. FIG. 3 shows an orbit profile of a macro spin caused by application of an electric field. Here, a set parameter is defined as follows: a damping constant of 0.01, a gyromagnetic constant of 2.34×10⁵ (m/A sec), anisotropy magnetic fields of x-axis and z-axis directions (in-plane) of 400 Oe and 200 Oe (coercive force), and a demagnetizing field in the y-axis direction (a perpendicular direction) plus a uniaxial anisotropy magnetic field of 5000 Oe. Here, an external magnetic field of 2900 Oe is applied in the y-axis direction in order to set an initial magnetized state to the off-point in FIG. 3. The following case is taken into consideration: a voltage is applied to the magnetic function element in this initial magnetized state, such that anisotropy in the y-axis direction changes by 20% (−1000 Oe). FIG. 3 shows that when a rising time period in applying the voltage is sufficiently short ; that is, equal to 1 ns or shorter, a spin having torque generated out of an anisotropy magnetic filed change converges on another stabilization point in the z-axis direction (on-point in FIG. 3). When the rising time period is longer than 1 ns, the spin converges on the stabilization point of the initial state again. Hence, controlling the rising time period in applying a pulse voltage is essential in writing of the magnetized state. A writing speed in the magnetized state is several times to several tens of times as fast as a writing speed observed in writing using a current-induced magnetic field and the spin transfer torque both of which are currently proposed based on a conventional MRAM. This indicates suitability for application to memories which requires high-speed processing. Once the spin has converged, the pulse voltage is reduced in a time period slower than a relaxation time period of magnetization. This reduction makes possible maintaining the magnetization direction after the pulse voltage is removed. The relaxation time period of magnetization T is expressed as follows:

$$τ = \frac{γ {H}_{eff}}{α} \qquad [ Equation 3 ]$$

where γ is a gyromagnetic constant, H_{eff} is an effective magnetic field, and a is a Gilbert damping constant. Thus, the rising time period of the pulse voltage is required to be set shorter than the relaxation time period of magnetization, and the rising time period is required to be set longer than the relaxation time period of magnetization.

On the other hand, the following case is taken into consideration: the perpendicular magnetic anisotropy energy is set to 101% to 150% of the shape magnetic anisotropy energy, and the external magnetic field is applied in a film (the magnetic layer 10)-in-plane direction. The magnetization forms an appropriate angle with the normal line of the film. In the above condition, application of a voltage may also switch a film-perpendicular component of magnetization.

FIG. 4 shows the result of an experiment conducted as follows: a voltage was externally applied to a magnetic function element whose magnetic layer 10 (film thicknesses are 0.38 nm, 0.48 nm, and 0.58 nm) employs Fe₈₀Co₂₀; and a change of the magnetic anisotropy of the magnetic function element was detected as a change of a magnetic hysteresis loop employing the Magneto-Optical effect (Polar MOKE). The substrate 13 is made of magnesium oxide single crystals (001). The base layer 14 is formed of epitaxial multilayer films (001) made of gold and chrome. The magnetic layer 10 is formed of a CoFe (001) film (film thickness of 2 nm or thinner). The insulating layer 11 is formed of an MgO (001) layer (10 nm)/polyimide (1.5 μm) stacked film. The upper electrode 12 is made of ITO.

As shown in FIG. 4, when the magnetic layer 10 is formed of Fe with 20% Co added, the magnetic layer 10 having CoFe develops perpendicular magnetic anisotropy in the film thickness of 2 nm similar to the case where the magnetic layer 10 is formed of Fe. However, by making the film thickness 0.5 nm or less, the magnetic layer 10 can work as a perpendicular magnetic film.

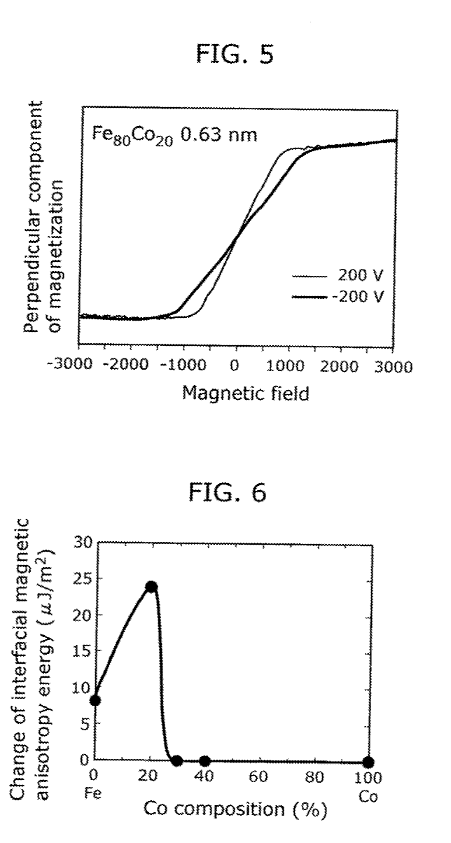

FIG. 5 shows that a voltage of ±200V is externally applied to the magnetic function element whose magnetic layer 10 employs Fe₈₀Co₂₀ with a film thickness of 0.63 nm, so that a change of the magnetic anisotropy of the magnetic function element is shown as a change of a magnetic hysteresis loop.

As shown in FIG. 5, voltage application changes the interfacial magnetic anisotropy energy by 21 μJ/m². A comparison shows that the magnetic layer 10 formed of FeCo is 2.5 times as great as that formed of Fe in a change amount of interfacial magnetic anisotropy energy. This means that controlling Co composition is essential in a magnetic anisotropy change caused by voltage.

FIG. 6 shows Co composition dependence of a change amount of interfacial magnetic anisotropy energy when a voltage of ±200V is externally applied to a magnetic function element. Here, the magnetic function element includes the magnetic layer 10 made of an iron-cobalt alloy with a film thickness of approximately 0.5 nm.

As shown in FIG. 6, the voltage effect efficiently increases when Co to be added accounts for less than 30% of Fe.

Next, the following is described; how the magnetization reversal is controlled utilizing a coercive force change found in the magnetic layer 10 and caused by either (i) voltage application to the electrode 12 and the base layer 14 or (ii) electric field application to the magnetic layer 10 and the insulating layer 11.

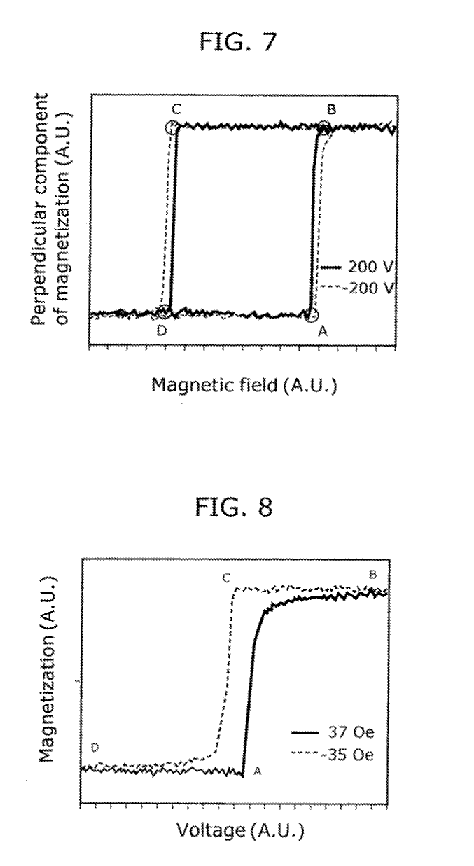

FIG. 7 shows that a voltage of ±200V is externally applied to a magnetic function element whose magnetic layer 10 employs Fe₈₀Co₂₀ with film thickness of 0.48 nm, so that a change of the magnetic anisotropy of the magnetic function element is shown as a change of a magnetic hysteresis loop.

As shown in FIG. 7, a film of Fe₈₀Co₂₀ having a film thickness of 0.48 nm is a perpendicular magnetic film. This makes the hysterisis excellent square-wise, and provides the film a coercive force. In addition, it can be seen that the coercive force changes according to voltage application. Hereinafter, a magnetization reversal controlling method using coercive force change shall be described.

First, as an initial state, an external magnetic filed is applied to the magnetic function element to hold the magnetized state at A in FIG. 7. In the magnetized state, a voltage is applied so that the electrode 12, such as an ITO electrode, is positive. This voltage application decreases the coercive force of the magnetic layer 10, and the magnetized state A transits to the magnetized state B in FIG. 7. FIG. 8 exemplifies the transition process. As shown in FIG. 8, application of an external magnetic field of 37 Oe, with no voltage applied, develops the magnetized state A in FIG. 8. When a positive voltage equal to 30V or lower is applied to the electrode 12, the magnetized state A transits to the state B in FIG. 8. Application of an external magnetic field of −35 Oe causes the magnetized state to transit to the state C in FIG. 8. When a negative voltage is applied to the electrode 12, application of the negative voltage equal to 30V or lower causes the magnetized state to transit to the state D in FIG. 8. Taking advantage of the above phenomena, the magnetization reversal can be controlled under a certain external assist magnetic field, utilizing the coercive force change caused by a voltage.

Hence, in the magnetic function element according to Embodiment 1, (i) the coercive force of the magnetic layer 10 may be changed by either application of a voltage, with a magnetic field externally applied to the magnetic function element, to opposing electrodes (the electrode 12 and the base layer 14) having a sandwiched structure including the magnetic layer 10 and the insulating layer 11 or application of an electric field to the structure, and the magnetization direction of the magnetic layer 10 may be controlled via the change of the coercive force.

As described above, CoFe is effective for a technique to change interfacial magnetic anisotropy energy utilizing a voltage or an electric field generated by the voltage. In order to further increase the effectiveness, it is essential that the material of an insulating layer, which is a potential barrier material, has high relative permittivity at room temperature. This is because the change amount of the interfacial magnetic anisotropy energy depends on an amount of charge accumulated in a bonding interface by application of a voltage. This means that a material having higher relative permittivity allows the film thickness of a magnetic layer to be made thicker than a material which does not have high relative permittivity even though the same interfacial magnetic anisotropy energy change is induced. Hence, the high relative permittivity is essential in view of maintaining excellent thermal stability when the technique is employed for an information storage method and a magnetic function element. For example, a thermal stability constant of Fe₈₀Co₂₀ (0.48 nm)/MgO junction having shown perpendicular magnetic in FIG. 7 is approximately five in the case where an element size of 100 nm×100 nm is considered. This constant is smaller than the practically required constant of 60. When SrTiO₃ (relative permittivity: approximately 300), whose relative permittivity is approximately 30 times as high as that of MgO at room temperature, is used as an insulating material, the insulating layer made of SrTiO₃ can induce the same interfacial magnetic anisotropy energy change as an insulating layer having the film thickness of Fe₈₀Co₂₀ (approximately 14 nm) 30 times as thick as that of the insulating layer made of SrTiO₃. Here, the thermal stability constant is approximately 150, which fully exceeds a standard value required in practice.

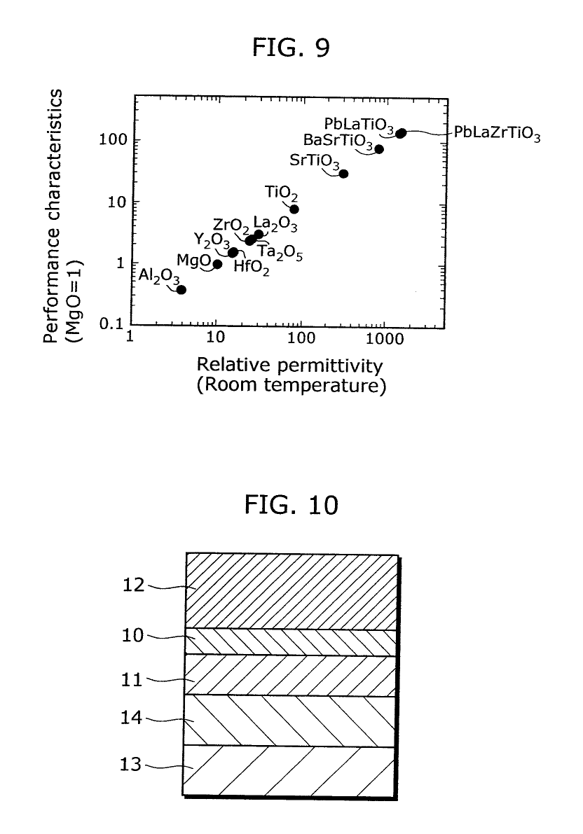

FIG. 9 shows how performance characteristics change depending on a material of the insulating layer 11. Here, the performance characteristics are predicted where (i) the magnetic anisotropy energy change of the magnetic layer 10 is 1 when the insulating layer 11 is made of MgO (relative permittivity of 9.8), and (ii) the magnetic anisotropy changes in proportion to an amount of charge accumulated on a layer between the magnetic layer 10 and the insulating layer 11.

According to FIG. 9, the following are suitable as a material for the insulating layer 11: a material made of BaTiO₃; namely a ferrodielectric substance material, with Sr, Sn, La, Zr, Ca, Y, Nd, Sm and Dy added and a Curie temperature and a dielectric constant controlled; SrTiO₃ which has a small mismatch rate of 1 to 2% with a bcc-Fe (001) alloy and a bcc-CoFe (001) alloy, and can epitaxially-grow; an oxide having a IIIB element (Y₂O₃ and La₂O₃); an oxide having a IVB element (ZrO₂ and HfO₂); an oxide having a VB element (Ta₂O₅); and TiO₂.

As described above, the magnetic function element according to an implementation of the present invention includes: the magnetic layer 10 which is an ultrathin film ferromagnetic layer having a film thickness of one or more atomic layers and of 2 nm or less; and the insulating layer 11 provided on the magnetic layer 10 and working as a potential barrier. The magnetization direction of the ultrathin film ferromagnetic layer 10 is controlled either by (i) applying a voltage to the opposing electrodes; namely the electrode 12 and the base layer 14, having the structure sandwiched, or (ii) applying an electric field to the structure to change magnetic anisotropy of the magnetic layer 10. Hence, the magnetic function element can control the magnetization direction with low power consumption without utilizing current-induced magnetic field or spin transfer torque.

### Embodiment 2

FIG. 10 is a cross-sectional view of a magnetic function element according to Embodiment 2 in the present invention.

The magnetic function element has the magnetic layer 10 and the insulating layer 11 of Embodiment 1 switch their positions. The insulating layer 11, working as a potential barrier, is provided on the substrate 13 and the base layer 14. Here, the base layer 14 can be also used as a bottom electrode. On the insulating layer 11, the magnetic layer 10 is provided. Here, the magnetization reversal of the magnetic layer 10 is to be induced by an electric field. A voltage is applied between the electrode 12 provided on the magnetic layer 10 and the base layer 14.

As described above, the magnetic function element according to an implementation of the present invention includes a structure having: the magnetic layer 10 which is an ultrathin film ferromagnetic layer having a film thickness of one or more atomic layers and of 2 nm or less; and the insulating layer 11 working as a potential barrier, and provided in contact with the magnetic layer 10. Magnetic anisotropy of the magnetic layer 10 is changed via application of either (i) a voltage to the opposing electrodes; namely the electrode 12 and the base layer 14, having the structure sandwiched, or (ii) an electric field to the structure. The change controls a magnetization direction of the magnetic layer 10. Hence, the magnetic function element can control the magnetization direction with low power consumption utilizing no current-induced magnetic field or spin transfer torque.

### Embodiment 3

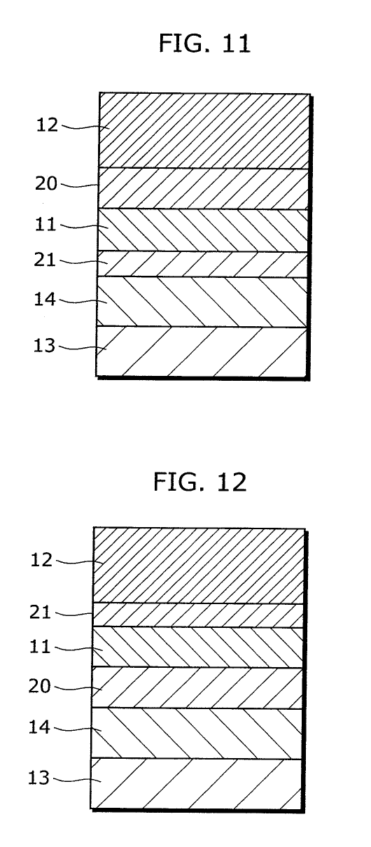

FIG. 11 is a cross-sectional view of a magnetic storage element (information storage element) according to Embodiment 3 in the present invention.

The magnetic storage element works as a single memory cell. The magnetic storage element is structured to have an extra magnetic layer (reference layer) 20 on the insulating layer 11 found in the magnetic function element according to Embodiment 1. A storage layer 21 is considered and structured in a similar manner (materials and film thickness) as the magnetic layer 10 in the magnetic function element according to Embodiment 1.

Including ferromagnetic metal, the reference layer 20 is sandwiched between the electrode 12 and the base layer 14, and stacked opposite the insulating layer 11 in relation to the storage layer 21. The reference layer 20 is made of the same material as the magnetic layer 10 is made. The magnetized state of the reference layer 20 remains fixed. Information is written by applying a voltage to control only the magnetized state of the storage layer 21. Here, the Magneto-Resistive-Effect is employed to read information. The Magneto-Resistive-Effect depends on a relative angle formed by magnetization of the storage layer 21 and the reference layer 20.

The base layer 14 is one of opposing electrodes included in the magnetic storage element. Provided on the substrate 13, the base layer 14 works as a base to grow the storage layer 21 or the reference layer 20.

Using a magnetization direction control technique similar to that employed for the magnetic function element according to Embodiment 1, the magnetic function element controls a magnetization direction of the storage layer 21 to store information. Hence, the magnetic function element can control the magnetization direction with low power consumption utilizing no current-induced magnetic field or spin transfer torque. Thus, by arranging such magnetic storage elements in a matrix, a magnetic random access memory with low power consumption will be produced.

### Embodiment 4

FIG. 12 is a cross-sectional view of a magnetic storage element (information storage element) according to Embodiment 4 in the present invention.

The magnetic storage element works as a single memory cell. The magnetic storage element is structured to have an extra magnetic layer (reference layer) 20 on the base layer 14 found in the magnetic function element according to Embodiment 2. The storage layer 21 corresponds to the magnetic layer 10 in the magnetic function element according to Embodiment 2, and has the same structure (materials and film thickness) as the magnetic layer 10.

The reference layer 20, which includes ferromagnetic metal, is sandwiched between the electrode 12 and the base layer 14, and stacked opposite the insulating layer 11 in relation to the storage layer 21. The reference layer 20 is made of the same material as the magnetic layer 10 is made. Similar to the case of the magnetic storage element according to Embodiment 3, the magnetized state of the reference layer 20 remains fixed. Information is written by applying a voltage so as to control only the magnetized state of the storage layer 21. The reading is performed employing the Magneto-Resistive-Effect which dependent on a relative angle formed by magnetization of the storage layer 21 and the reference layer 20.

As described above, the magnetic function element according to Embodiment 4 stores information. The magnetic function element includes: the storage layer 21 which is an ultrathin film ferromagnetic layer having (i) one or more atomic layers and (ii) a film thickness of equal to 2 nm or less; the insulating layer 11 working as a potential barrier, and provided in contact with the storage layer 21; and the electrode 12 and the base layer 14 working as a pair of opposing electrodes sandwiching the storage layer 21 and the insulating layer 11. Using a magnetization direction control technique similar to that employed for the magnetic function element according to Embodiment 1, the magnetic function element controls a magnetization direction of the storage layer 21 to store information. Hence, the magnetic function element can control the magnetization direction with low power consumption utilizing no current-induced magnetic field or spin transfer torque. Thus, by arranging such magnetic storage elements in a matrix, a magnetic random access memory with low power consumption will be produced.

### Embodiment 5

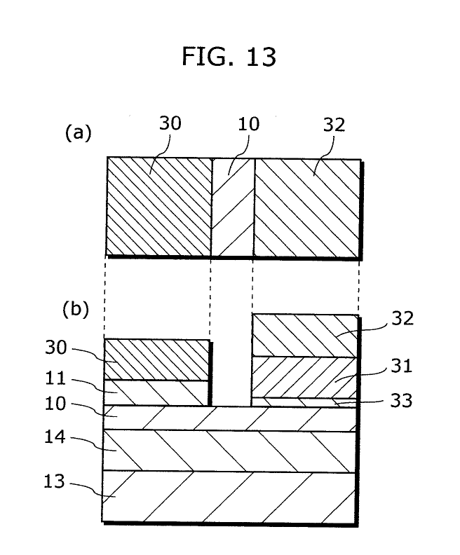

FIG. 13 shows a structure of a spin transistor according to Embodiment 5 in the present invention. It is noted that FIGS. 13(a) and 13(b) respectively show a top view and a cross-sectional view of the spin transistor.

This spin transistor is a magnetic function element taking advantage of a Magneto-Resistance Effect change caused by having a voltage applied. The spin transistor includes the following: the substrate 13, the base layer 14, the magnetic layer 10, the insulating layer 11, an electrode 30, a nonmagnetic layer 33, a magnetic layer 31, and an electrode 32. The reference layer 31 is made of the same material as the magnetic layer 10.

One of the features of the spin transistor is that a gate unit and a reading unit are formed spaced. Here, the gate unit has the voltage applied to control a magnetization direction of the magnetic layer 10, and the reading unit reads a magnetized state of the magnetic layer 10.

The gate unit includes the insulating layer 11 and the electrode 30 both provided on the magnetic layer 10. The voltage is applied between the electrode 30 and the base layer 14.

The reading unit includes the following provided on the magnetic layer 10: the nonmagnetic layer 33, the magnetic layer 31, and the electrode 32. The nonmagnetic layer 33 may be made of: (i) a noble metal including the following: gold (Au), silver (Ag), copper (Cu), aluminum (Al), chrome (Cr), and ruthenium (Ru), (ii) a transition metal element, and (iii) an oxide, a nitride, and a fluoride of the aluminum, magnesium, hafnium, cerium, strontium, tantalum, and titan.

The Magneto-Resistive-Effect is employed to read the magnetized state. The Magneto-Resistive-Effect depends on a relative angle formed by magnetization of the magnetic layer 10 and the magnetic layer 31 lying between the electrode 32 and the base layer 14. By choosing (i) the most suitable material and film thickness for the nonmagnetic layer 33, and (ii) the best-matched element sizes for the gate unit and the reading unit, it is possible to design an independent device that is appropriate for each of information writing by application of a gate voltage and information reading using the Magneto-Resistive-Effect. This structure makes possible controling the current which flows into the reading unit by application of the gate voltage. A typical field effect transistor might be capable of this operation. However, the spin transistor according to Embodiment 5 includes the magnetic layer 10 working as a storage layer, and thus works as a nonvolatile transistor. Accordingly, the spin transistor is capable of amplifying a current, a voltage, and power, as well as of switching.

As described above, the spin transistor according to Embodiment 5 is a magnetic function element having three terminals and capable of working as at least one of a memory and a switch. The spin transistor includes: the base layer 14 connected to a first terminal and working as a first electrode layer; the magnetic layer 10 which is an ultrathin film ferromagnetic layer (i) provided on the base layer 14 and (ii) having a film thickness of one or more atomic layers and of 2 nm or less; the insulating layer 11 provided on a part of a top surface of the magnetic layer 10, and working as a potential barrier; the electrode 30 formed on the insulating layer 11, connected to a second terminal, and working as a second electrode layer; the nonmagnetic layer 33 provided on an other part of the top surface of the magnetic layer 10; the magnetic layer 31 provided on the nonmagnetic layer 33; and the electrode 32 provided on the magnetic layer 31, connected to a third terminal, and working as a third electrode layer. A current flowing between the first terminal and the second terminal changes depending on a relative angle formed by magnetization of the magnetic layer 10 and the magnetic layer 31. Thus, by controlling the relative angle formed by magnetization of the magnetic layer 10 and the magnetic layer 31, it is possible to amplify a current running between the first terminal and the second terminal. Furthermore, by measuring the current running between the first terminal and the second terminal, the relative angle formed by magnetization of the magnetic layer 10 and the magnetic layer 31 can be specified. This feature shows that the spin transistor can operate as a memory. Here, using a magnetization direction control technique similar to that employed for the magnetic function element according to Embodiment 1, the spin transistor controls a magnetization direction of the magnetic layer 10. Accordingly, the spin transistor can carry out an amplification function and a memory function with low power consumption.

### Embodiment 6

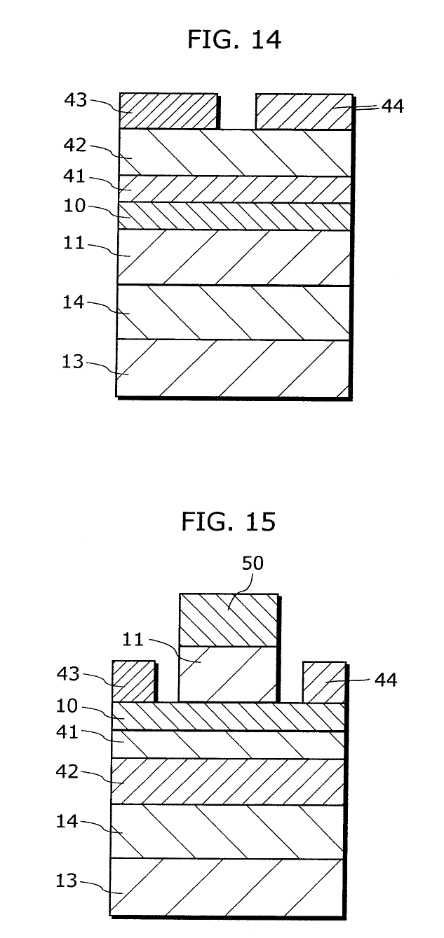

FIG. 14 is a cross-sectional view of a magnetic function element according to Embodiment 6 in the present invention.

The magnetic function element, which works as a magnetic storage element and a spin transistor, includes the following: the substrate 13, the base layer 14, the insulating layer 11, the insulating layer 10, a nonmagnetic layer 41, a magnetic layer 42, and electrodes 43 and 44. The magnetic layer 42 is made of the same material as the magnetic layer 10 is made.

The nonmagnetic layer 41 may be made of: (i) a noble metal including the following: gold (Au), silver (Ag), copper (Cu), aluminum (Al), chrome (Cr), and ruthenium (Ru), (ii) a transition metal element, and (iii) an oxide, a nitride, and a fluoride of the aluminum, magnesium, hafnium, cerium, strontium, tantalum, and titan.

The magnetic function element is structured as follows: the insulating layer 11 is provided on the substrate 13 via the base layer 14; and the magnetic layer 10 is provided on the insulating layer 11. Here, a magnetization direction of the magnetic layer 10 is controlled by a voltage or an electric field developed by the voltage. The base layer 14 can be also used as a bottom electrode.

Moreover, the magnetic function element has (i) the nonmagnetic layer 41 and the magnetic layer 42 provided on the magnetic layer 10, and (ii) the electrodes 43 and 44 placed on both ends of a three-layer construction including the magnetic layer 10, the nonmagnetic layer 41, and the magnetic layer 42. Here, the nonmagnetic layer 41 and the magnetic layer 42 are made of either a metal or an insulating material.

The magnetic function element is designed to develop the Magneto-Resistance Effect between the magnetic layer 10 and the magnetic layer 42 having the nonmagnetic layer 41 in between. A voltage is applied between the electrode 43 or the electrode 44 and the base layer 14 working as a bottom electrode, so that a magnetization direction of the magnetic layer 10 is controlled. The Magneto-Resistance Effect, developed by a change of relative magnetization directions of the magnetic layer 10 and the magnetic layer 42 via the nonmagnetic layer 41, is detected between the electrodes 43 and 44. Here, the following case is taken into consideration: the voltage applied between the electrode 43 or the electrode 44 and the base layer 14 is a gate voltage. By controlling the magnetization direction of the magnetic layer 10 using the gate voltage, a current running between the electrodes 43 and 44 can be controlled. Accordingly, the magnetic function element works as a field effect transistor. Having the magnetic layer 10 as a control layer, in addition, the magnetic function element can be produced as a non-volatile spin transistor.

As described above, the magnetic function element according to Embodiment 6 is a magnetic function element having three terminals and capable of working as at least one of a memory and a switch. The magnetic function element includes: the magnetic layer 10 which is an ultrathin film ferromagnetic layer having a film thickness of one or more atomic layers and of 2 nm or less; the insulating layer 11 working as a potential barrier, and provided in contact with a bottom surface of the magnetic layer 10; the base layer 14 formed under the insulating layer 11, and connected to the first terminal; the nonmagnetic layer 41 provided on the magnetic layer 10; the magnetic layer 42 provided on the nonmagnetic layer 41; the electrode 43 provided on a part of a top surface of the magnetic layer 42, and connected to the second terminal; and the electrode 44 provided on an other part of the top surface of the magnetic layer 42, and connected to the third terminal. A current flowing between the first terminal and the second terminal changes depending on a relative angle formed by magnetization of the magnetic layer 10 and the magnetic layer 42. Thus, by controlling the relative angle formed by magnetization of the magnetic layer 10 and the magnetic layer 42, it is possible to amplify a current running between the first terminal and the second terminal. Furthermore, by measuring the current running between the first terminal and the second terminal, the relative angle formed by magnetization of the magnetic layer 10 and the magnetic layer 42 can be specified. This feature shows that the spin transistor can operate as a memory. Here, using a magnetization direction control technique similar to that employed for the magnetic function element according to Embodiment 1, the magnetic function element controls a magnetization direction of the magnetic layer 10. Accordingly, the magnetic function element can work as a spin transistor carrying out an amplification function and a memory function with low power consumption, and a magnetic storage element with low power consumption.

### Embodiment 7

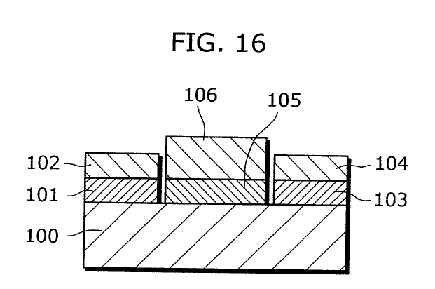

FIG. 15 is a cross-sectional view of a magnetic function element according to Embodiment 7 in the present invention.

The magnetic function element works as a magnetic storage element and a spin transistor. The magnetic function element includes the following: the substrate 13, the base layer 14, the magnetic layer 42, the nonmagnetic layer 41, the magnetic layer 10, the insulating layer 11, the electrodes 43 and 44, and an electrode 50.

Based on the structure of the magnetic function element according to Embodiment 7, the magnetic function element according to Embodiment 7 is sandwich-structured with the following provided on the substrate 13: the magnetic layer 42, the nonmagnetic layer 41, and the magnetic layer 10. In addition, on the magnetic layer 10, the insulating layer 11 working as a potential barrier, and the electrode 50 are provided. Here, the magnetic layer 10 has a voltage applied to act as a magnetization control layer; specifically, a voltage is applied between the base layer 14 working as a bottom electrode and the electrode 50, so that a magnetization direction of the magnetic layer 10 is controlled. Similar to the case of the Magneto-Resistance Effect element according to Embodiment 6, the magnetic layer 10, the nonmagnetic layer 41, and the magnetic layer 42 bring about the Magneto-Resistance Effect depending on a relative angle of the magnetization directions formed by magnetization of the magnetic layer 10 and the magnetic layer 42. The Magneto-Resistance Effect is detected between the electrodes 43 and 44 placed at both ends of the three-layer construction.

Here, when the magnetic function element is regarded to work as a magnetic storage element, a writing operation is carried out in a manner such that a voltage is applied between the base layer 14 and the electrode 50, so that the magnetization direction of the magnetic layer 10 is controlled. A reading operation is carried out employing the Magneto-Resistance Effect observed between the electrodes 43 and 44. Concurrently, when the magnetic function element is regarded to work as a spin transistor, a voltage applied between the electrode 50 and the base layer 14 is regarded as a gate voltage. Here, the gate voltage controls the magnetization direction of the magnetic layer 10, which makes possible controlling a current running between the electrodes 43 and 44. Accordingly, the magnetic function element according to Embodiment 7 works as a field effect transistor. Having the magnetic layer 10 as a control layer, in addition, the magnetic function element can be produced as a non-volatile spin transistor.

As described above, the magnetic function element according to Embodiment 7 is a magnetic function element having three terminals and capable of working as at least one of a memory and a switch. The magnetic function element includes: the magnetic layer 42, the nonmagnetic layer 41 provided on the magnetic layer 42, the magnetic layer 10 which is an ultrathin film ferromagnetic layer (i) provided on the nonmagnetic layer 41, and (ii) having a film thickness of one or more atomic layers and of 2 nm or less; the insulating layer 11 working as a potential barrier, and provided on a part of a top surface of the magnetic layer 10; the electrode 50 formed on the insulating layer 11 and connected to the first terminal; and the electrodes 43 and 44 both provided on other parts of a top surface of the magnetic layer 10, and respectively connected to the second and the third terminals. A current flowing between the first terminal and the second terminal changes depending on a relative angle formed by magnetization of the magnetic layer 10 and the magnetic layer 42. Thus, by controlling the relative angle formed by magnetization of the magnetic layer 10 and the magnetic layer 42, it is possible to amplify a current running between the first terminal and the second terminal. Furthermore, by measuring the current running between the first terminal and the second terminal, the relative angle formed by magnetization of the magnetic layer 10 and the magnetic layer 42 can be specified. This feature shows that the spin transistor can operate as a memory. Here, using a magnetization direction control technique similar to that employed for the magnetic function element according to Embodiment 1, the magnetic function element controls a magnetization direction of the magnetic layer 10. Accordingly, the magnetic function element can work as a spin transistor carrying out an amplification function and a memory function with low power consumption, and a magnetic storage element with low power consumption.

### Embodiment 8

FIG. 16 is a cross-sectional view of a magnetic function element according to Embodiment 8 in the present invention.

The magnetic function element has three terminals and works as a magnetic storage element and a spin transistor. The magnetic function element includes: a first magnetic layer 101 which is an ultrathin film ferromagnetic layer formed on a part of a top surface of a semiconductor layer 100, and having a film thickness of one or more atomic layers and of 2 nm or less; a first electrode 102 formed on the first magnetic layer 101; a second magnetic layer 103 formed on a part of the top surface of the semiconductor layer 100; a second electrode 104 formed on the second magnetic layer 103; a gate insulating film 105 formed on a part of the top surface of the semiconductor layer 100; and a third electrode 106 formed on and connected with the gate insulating film 105.

The magnetic function element has (i) a voltage applied between the first electrode 102 and the second electrode 104 or (ii) an electric field applied to the first magnetic layer 101 in order to change magnetic anisotropy of the first magnetic layer 101. The change controls a magnetization direction of the first magnetic layer 101.

Although only some exemplary Embodiments of this invention have been described in detail above, those skilled in the art will readily appreciate that many modifications are possible in the exemplary Embodiments without materially departing from the novel teachings and advantages of this invention. Accordingly, all such modifications are intended to be included within the scope of this invention.

The above Embodiments have exemplified a magnetic storage element and a spin transistor as a magnetic function element; concurrently, the above Embodiments may for example introduce, as the magnetic function element, (i) a switching element taking advantage of a change of the Magneto-Resistance Effect caused by electric field application, and (ii) a nonvolatile logical circuit using a switching element and a spin transistor.

### INDUSTRIAL APPLICABILITY

The present invention can be used for a magnetization control method, an information storage method, an information storage element, and a magnetic function element. In particular, the present invention is used for a magnetic random access memory and a spin transistor.

1. A magnetization control method of controlling a magnetization direction of a magnetic layer, said method comprising:
forming a structure including (i) an ultrathin film ferromagnetic layer having a film thickness of one or more atomic layers and of 2 nm or less, and (ii) an insulating layer provided on the ultrathin film ferromagnetic layer and working as a potential barrier; and
controlling a magnetization direction of the ultrathin film ferromagnetic layer by applying either (i) a voltage to opposing electrodes sandwiching the structure or (ii) an electric field to the structure to change magnetic anisotropy of the ultrathin film ferromagnetic layer.

2. The magnetization control method according to claim 1,
wherein said forming the structure includes forming, as the insulating layer, an insulating layer having a value of resistance per unit area of 10 Ωm² or greater.

3. The magnetization control method according to claim 1,
wherein said forming the structure includes determining a film thickness of the ultrathin film ferromagnetic layer so that the film thickness develops, in the ultrathin film ferromagnetic layer, transition between in-plane magnetic anisotropy and shape magnetic anisotropy, the transition being caused by an electric field generated on an interface between the ultrathin film ferromagnetic layer and the insulating layer.

4. The magnetization control method according to claim 1,
wherein said controlling involves applying the voltage so that perpendicular magnetic anisotropy energy generated in the ultrathin film ferromagnetic layer accounts for 50% to 99% of shape magnetic anisotropy energy observed when the magnetization is oriented perpendicular to a plane.

5. The magnetization control method according to claim 1,
wherein said controlling involves applying, as the voltage, a voltage changing stepwise.

6. The magnetization control method according to claim 5,
wherein said controlling involves applying, as the voltage, a pulse voltage (i) whose rising time period is equal to or shorter than a magnetic relaxation time period of the ultrathin film ferromagnetic layer, and (ii) whose falling time period is equal to the magnetic relaxation time period of the ultrathin film ferromagnetic layer or longer.

7. The magnetization control method according to claim 1,
wherein said controlling involves sweeping voltages having opposite polarities and applying the voltages to the structure in order to control the magnetization direction of the ultrathin film ferromagnetic layer.

8. The magnetization control method according to claim 1,
wherein said forming the structure involves forming the ultrathin film ferromagnetic layer made of an iron-cobalt alloy whose Co composition accounts for less than 30%.

9. The magnetization control method according to claim 1,
wherein said forming the structure involves forming the ultrathin film ferromagnetic layer including one of an alloy, an ordered alloy, and a multilayer laminated structure each made of (i) one of Fe, Co, and Ni as a magnetic transition metal, and (ii) one of Pt, Pd, Ru, and Re.

10. The magnetization control method according to claim 1,
wherein said forming the structure involves forming the insulating layer made of a paraelectric having high relative permittivity at a room temperature.

11. The magnetization control method according to claim 1,
wherein said controlling involves changing a coercive force of the ultrathin film ferromagnetic layer via the application of either (i) the voltage to the opposing electrodes sandwiching the structure or (ii) the electric field to the structure in order to control the magnetization direction of the ultrathin film ferromagnetic layer, the voltage and the electric field being applied with a magnetic externally applied.

12. A magnetization control method executed by a magnetic function element which has three terminals, works as at least one of a memory and a switch, and includes a first magnetic layer (i) formed on a top surface of a semiconductor layer, (ii) including an ultrathin film ferromagnetic layer having a film thickness of one or more atomic layers and of 2 nm or less, a first electrode formed on the first magnetic layer, a second magnetic layer formed on the top surface of the semiconductor layer, a second electrode formed on the second magnetic layer, a gate insulating film formed on the top surface of the semiconductor layer, and a third electrode formed on the gate insulating film, said method comprising
controlling a magnetization direction of the first magnetic layer by changing magnetic anisotropy of the first magnetic layer via application of either (i) a voltage between the first electrode and the second electrode or (ii) an electric field to the first magnetic layer.

13. A method for storing information which involves executing the magnetization control method according to claim 1 to control a magnetization direction.

14. An element which stores information, said element comprising:
an ultrathin film ferromagnetic layer having a film thickness of one or more atomic layers and of 2 nm or less;
an insulating layer provided on said ultrathin film ferromagnetic layer and working as a potential barrier; and
a pair of opposing electrodes sandwiching said ultrathin film ferromagnetic layer and said insulating layer.

15. The information storage element according to claim 14, further comprising
a reference layer sandwiched between said opposing electrodes, provided opposite said insulating layer in relation to said ultrathin film ferromagnetic layer, and including a ferromagnetic metal.

16. The information storage element according to claim 14, further comprising a substrate,
wherein one of said opposing electrodes is a base layer provided on said substrate, and working as a base to grow said ultrathin film ferromagnetic layer or said reference layer.

17. A magnetic function element which has three terminals and works as at least one of a memory and a switch, said element comprising:
a first electrode layer connected to a first terminal;
a first magnetic layer which is an ultrathin film ferromagnetic layer (i) provided on first electrode layer, and (ii) having a film thickness of one or more atomic layers and of 2 nm or less;
an insulating layer provided on a part of a top surface of said first magnetic layer, and working as a potential barrier;
a second electrode layer formed on said insulating layer and connected to a second terminal;
a nonmagnetic layer provided on an other part of the top surface of said first magnetic layer;
a second magnetic layer provided on said nonmagnetic layer; and
a third electrode layer provided on said second magnetic layer, and connected to said third terminal.

18. A magnetic function element which has three terminals and works as at least one of a memory and a switch, said element comprising:
a first magnetic layer which is an ultrathin film ferromagnetic layer having a film thickness of one or more atomic layers and of 2 nm or less;
an insulating layer working as a potential barrier, and provided in contact with a bottom surface of the first magnetic layer;
a first electrode layer formed under said insulating layer and connected to said first terminal;
a nonmagnetic layer provided on said first magnetic layer; and
a second magnetic layer provided on said nonmagnetic layer;
a second electrode layer provided on a part of a top surface of said second magnetic layer, and connected to said second terminal; and
a third electrode layer provided on an other part of the top surface of said second magnetic layer, and connected to said third terminal.

19. A magnetic function element which has three terminals and works as at least one of a memory and a switch, said element comprising:
a first magnetic layer;
a nonmagnetic layer provided on said first magnetic layer;
a second magnetic layer which is an ultrathin film ferromagnetic layer (i) provided on said nonmagnetic layer, and (ii) having a film thickness of one or more atomic layers and of 2 nm or less;
an insulating layer provided on a part of a top surface of said second magnetic layer, and working as a potential barrier;
a first electrode layer formed on said insulating layer and connected to a first terminal; and
a second electrode layer and a third electrode layer both provided on other parts of the top surface of said second magnetic layer, and respectively connected to a second terminal and a third terminal.
